(19) United States
(12) Patent Application Publication
(10) Pub. No.: US 2012/0257367 A1
(43) Pub. Date: Oct. 11, 2012

(54) PROTECTIVE JACKET AND WIRELESS COMMUNICATION DEVICE USING THE SAME

(75) Inventor: Ya-Chi Huang, Hsinchu (TW)

(73) Assignee: GEMTEK TECHNOLOGY CO., LTD., Hsinchu (TW)

(21) Appl. No.: 13/160,527

(22) Filed: Jun. 15, 2011

(30) Foreign Application Priority Data
Apr. 8, 2011 (TW) 100112225

(51) Int. Cl. H05K 7/02; H05K 5/00

(52) U.S. Cl. 361/807; 361/679.01

(57) ABSTRACT

A wireless communication device includes a host and a protective jacket. The host has a connector. The protective jacket includes a jacket and a cap. The jacket has a receiving space and an opening that communicates with the receiving space and the outside of the jacket. The cap is configured in the receiving space and opposite to the opening. The wireless communication device is placed in the receiving space and is in a first state or a second state relative to the jacket. When the wireless communication device is in the first state, the cap covers the connector. When the wireless communication device is in the second state, the connector passes through the opening and protrudes from the jacket.

### CROSS-REFERENCE TO RELATED APPLICATION

This application claims the priority benefit of Taiwan application serial no. 100112225, filed Apr. 8, 2011. The entirety of the above-mentioned patent application is hereby incorporated by reference herein and made a part of this specification.

### BACKGROUND OF THE INVENTION

1. Field of the Invention

The invention relates to a wireless communication device. More particularly, the invention relates to a wireless communication device having a protective jacket.

2. Description of Related Art

With the progress of information technology, various electronic devices (e.g., portably electronic devices especially) have been developed to be light, compact, and multi-functional. The volume of the portable electronic devices is decreased. Hence, if signals are transmitted to the portable electronic devices through wires, the portability of the electronic devices is reduced, and thus signals are transmitted wirelessly to most existing portable electronic devices. Nonetheless, some of the portable electronic devices do not have built-in wireless communication interfaces; accordingly, wireless communication devices that can be externally connected to the portable electronic devices have been introduced.

### SUMMARY OF THE INVENTION

The invention is directed to a protective jacket that allows an electronic device to be placed therein no matter whether the electronic device is in use or not.

The invention is further directed to a wireless communication device that has a protective jacket. The protective jacket is applicable regardless of the condition of use of the wireless communication device.

In an embodiment of the invention, a protective jacket for covering an electronic device is provided. The electronic device has a connector. The protective jacket includes a jacket, a fixing member, and a cap. The jacket has a receiving space and an opening that communicates with the receiving space and the outside of the jacket. The fixing member is configured on the jacket and outside the receiving space. The cap is configured in the receiving space and opposite to the opening. The electronic device is suitable for being placed in the receiving space and is in a first state or a second state relative to the jacket. When the electronic device is in the first state, the cap covers the connector. When the electronic device is in the second state, the connector passes through the opening and protrudes from the jacket.

In an embodiment of the invention, a wireless communication device that includes a host and a protective jacket is provided. The host has a connector. The protective jacket includes a jacket and a cap. The jacket has a receiving space and an opening that communicates with the receiving space and the outside of the jacket. The cap is configured in the receiving space and opposite to the opening. The host is suitable for being placed in the receiving space and is in a first state or a second state relative to the jacket. When the host is in the first state, the cap covers the connector. When the host is in the second state, the connector passes through the opening and protrudes from the jacket.

According to an embodiment of the invention, the cap and the opening are substantially located on the same axis.

According to an embodiment of the invention, the protective jacket further includes a fixing member that is configured on the jacket and outside the receiving space.

According to an embodiment of the invention, when the electronic device is in the second state, the jacket is fixed to a peripheral device by the fixing member.

According to an embodiment of the invention, when the electronic device is fixed to the peripheral device by the protective jacket, the connector of the electronic device is electrically connected to the peripheral device.

According to an embodiment of the invention, the electronic device further has an antenna opposite to the connector. When the electronic device is fixed to the peripheral device by the protective jacket, the antenna is located above the connector.

According to an embodiment of the invention, the cap, the fixing member, and the jacket are integrally foamed.

According to an embodiment of the invention, a material of the cap and the jacket is a thermoplastic elastomer.

According to an embodiment of the invention, the fixing member is a back clipping mechanism, a sucker, a Velcro tape, or a magnetic/magnetizing device.

According to an embodiment of the invention, the connector is a universal serial bus (USB) connector or a high definition multimedia interface (HDMI) connector.

Based on the above, in the wireless communication device described in the embodiments of the invention, the host is covered by the protective jacket. Therefore, when the wireless communication device is not in use, the connector can be directly covered by the cap of the protective jacket, so as to prevent the connector from moisture and dust. By contrast, once the wireless communication device is to be used, the wireless communication device can be turned upside down, such that the connector of the wireless communication device can pass through the opening of the protective jacket and protrude from the protective jacket. As a result, the connector of the wireless communication device can be electrically connected to the peripheral device, and the protective jacket can still serve to protect the host.

Other features and advantages of the invention will be further understood from the further technological features disclosed by the embodiments of the invention wherein there are shown and described embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view illustrating the assembly of a wireless communication device according to an embodiment of the invention.

FIG. 2 is a schematic view illustrating a condition of use of the wireless communication device depicted in FIG. 1.

FIG. 3A and FIG. 3B are schematic views illustrating that the host is in a first state relative to the protective jacket.

FIG. 4A and FIG. 4B are schematic views illustrating that the host is in a second state relative to the protective jacket.

FIG. 5 is a schematic view illustrating another condition of use of the wireless communication device depicted in FIG. 2.

### DESCRIPTION OF EMBODIMENTS

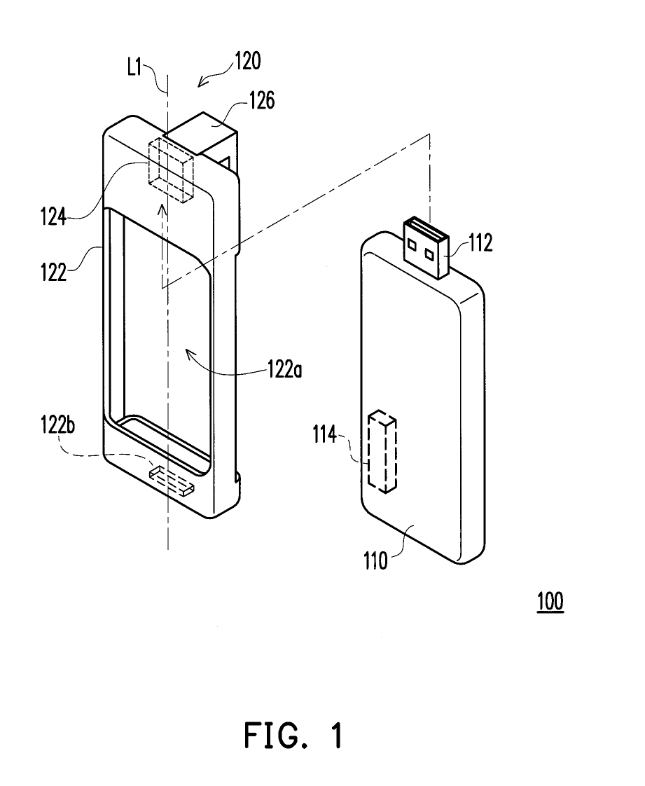

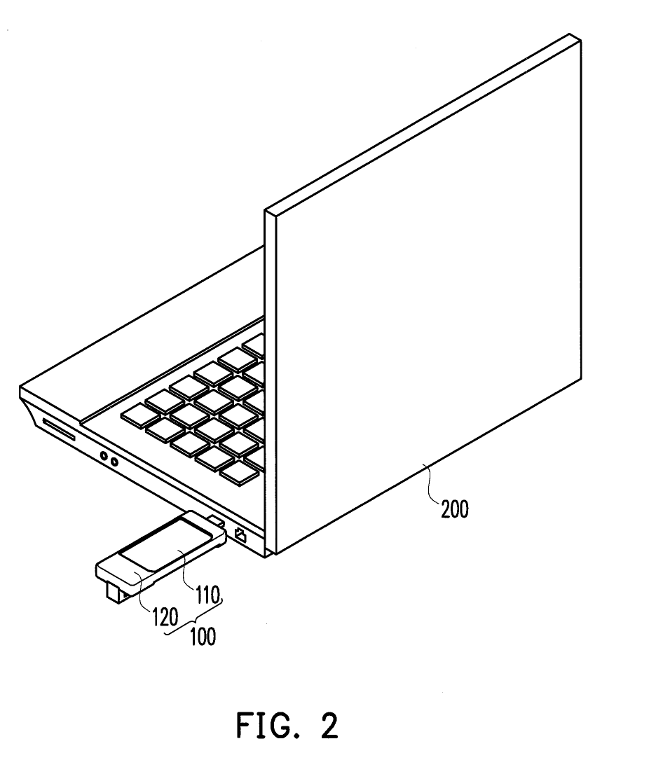

FIG. 1 is a schematic view illustrating the assembly of a wireless communication device according to an embodiment of the invention. FIG. 2 is a schematic view illustrating a condition of use of the wireless communication device depicted in FIG. 1. With reference to FIG. 1 and FIG. 2, in this embodiment, the wireless communication device 100 includes a host 110 and a protective jacket 120. The host 110 has a connector 112. The connector 112 is a USB connector or a HDMI connector, for instance. The wireless communication device 100 can be electrically connected to a peripheral device 200 (e.g., a computer or any other portable electronic device) by the connector 112, and thereby the peripheral device 200 can function as a wireless transceiver because of the electrical connection between the wireless communication device 100 and the peripheral device 200. The protective jacket 120 includes a jacket 122 and a cap 124. The jacket 122 has a receiving space 122a and an opening 122b that communicates with the receiving space 122a and the outside of the jacket 122. The cap 124 is configured in the receiving space 122a and opposite to the opening 122b. In this embodiment, the protective jacket 120 serves to cover and protect the host 110, and the configuration of the protective jacket 120 and the host 110 differs due to different conditions of use of the host 110.

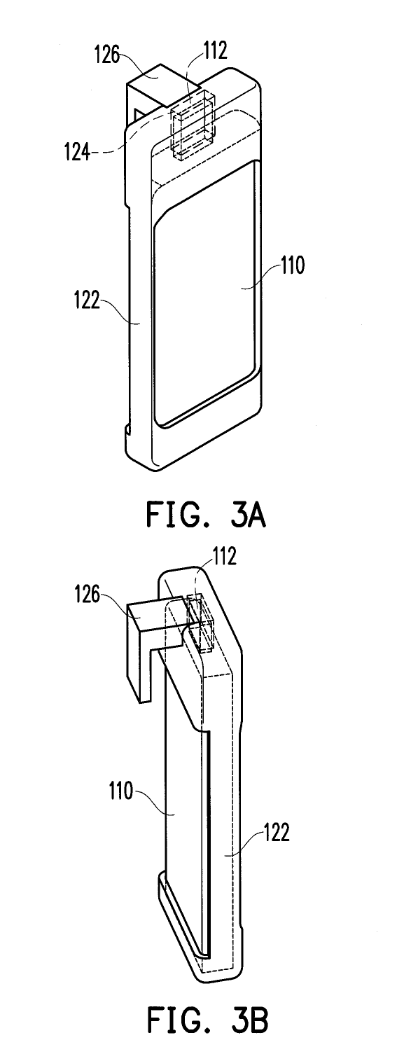

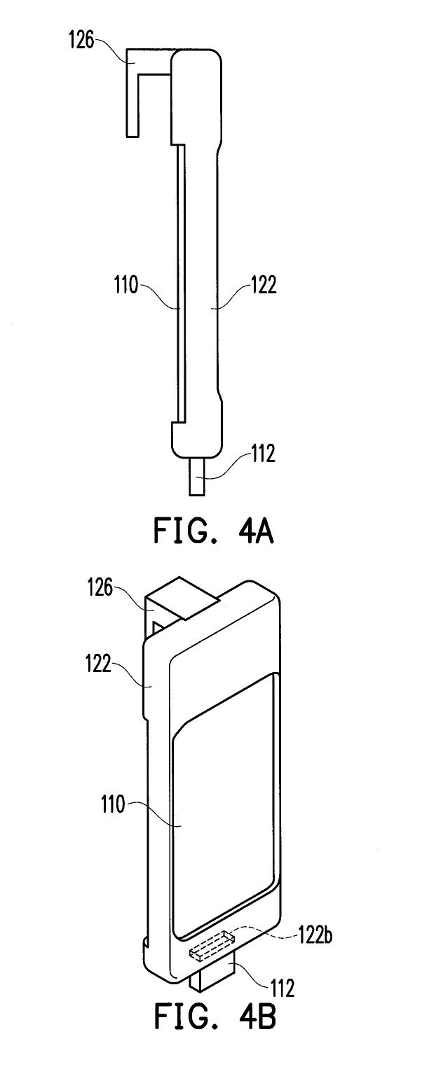

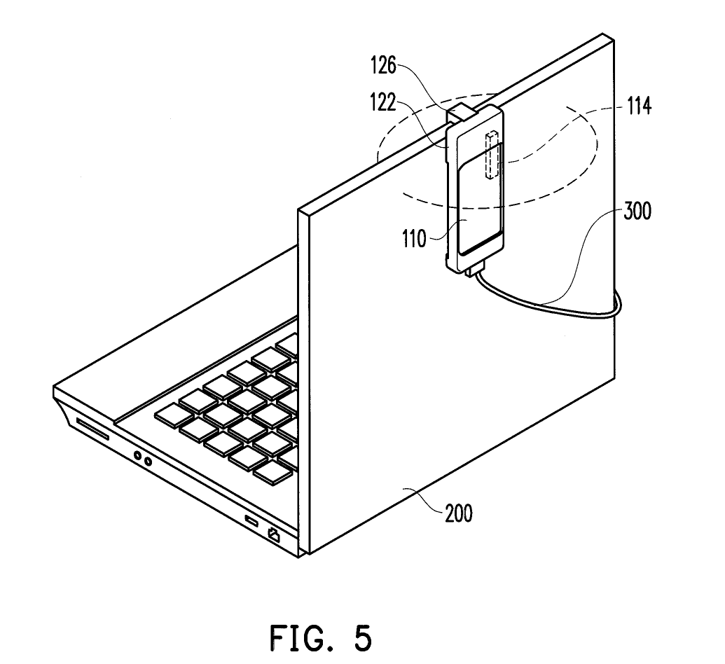

FIG. 3A and FIG. 3B are schematic views illustrating that the host is in a first state relative to the protective jacket. FIG. 4A and FIG. 4B are schematic views illustrating that the host is in a second state relative to the protective jacket. FIG. 5 is a schematic view illustrating another condition of use of the wireless communication device depicted in FIG. 2. With reference to FIG. 3A to FIG. 3B, FIG. 4A to FIG. 4B, and FIG. 5, in the wireless communication device 100 of this embodiment, the host 110 can be either in a first state (shown in FIG. 3A and FIG. 3B) or in a second state (shown in FIG. 4A and FIG. 4B) relative to the jacket 122 of the protective jacket 120. When the host 110 is in the first state relative to the jacket 122, the connector 112 of the host 110 is covered by the cap 124 located in the receiving space 122a. At this time, the wireless communication device 100 is not in use, and the cap 124 can better prevent the connector 112 from moisture and dust. By contrast, when the host 110 is in the second state relative to the jacket 122, the connector 112 in the receiving space 122a passes through the opening 122b and protrudes from the jacket 122. Thereby, the wireless communication device 100 can be electrically connected to the peripheral device 200 directly by the connector 112 (shown in FIG. 2) or through a cable 300 (shown in FIG. 5).

Specifically, in this embodiment, the cap 124 and the opening 122b in the receiving space 122a are opposite to each other. That is to say, the cap 124 and the opening 122b are substantially located on the same axis L1. Thereby, the protective jacket 120 is applicable even though the positions of the connector 112 and the host 110 in different states are relatively adjusted. Namely, when the wireless communication device 100 is not in use, the host 110 is configured in the jacket 122, and the connector 112 of the host 110 faces the cap 124. On the contrary, when the wireless communication device 100 is to be used, the protective jacket 120 can be removed from the host 110, and the host 110 rotates 180 degrees and is then placed into the protective jacket 120 again. Thereby, the connector 112 located at a side of the host 110 can pass through the opening 122b and protrude from the jacket 122. As such, the wireless communication device 100 can be electrically connected to the peripheral device 200 directly by the exposed connector 112, and the protective jacket 120 can still serve to protect the host 110. The locations of the cap 124 and the opening 122b on the jacket 122 are not limited in the invention and can be appropriately adjusted based on the configuration of the connector 112 of the host 110.

With reference to FIG. 4A, FIG. 4B, and FIG. 5, in this embodiment, the protective jacket 120 further includes a fixing member 126 that is configured on the jacket 122 and outside the receiving space 122a. In the protective jacket 120 of this embodiment, the jacket 122, the cap 124, and the fixing member 126 are integrally formed by a thermoplastic elastomer (e.g., rubber), such that the protective jacket 120 can prevent the host 110 therein from moisture and dust, or that the protective jacket 120 can act as a cushion to the host 110. The fixing member 126 allows the jacket 122 and the host 110 covered by the jacket 122 to be fixed to the peripheral device 200. In another embodiment that is not shown in the drawings, the wireless communication device 100 can be affixed to the user by the fixing member 126, so as to enhance portability of the wireless communication device 100. In this embodiment, the fixing member 126 is a back clipping mechanism, for instance, which should not be construed as a limitation to the invention. Any other member (e.g., a sucker, a magnet, or a Velcro tape) that can fix the jacket 122 and the host 110 to the peripheral device 200 is applicable in this embodiment.

Note that the host 110 in the wireless communication device 100 of this embodiment further has an antenna 114 opposite to the connector 112. Based on the corresponding configuration of the antenna 114 and the connector 112, the antenna 114 is substantially located above the connector 112 when the host 110 is fixed to the peripheral device 200 by the fixing member 126 of the protective jacket 120. Since the antenna 114 faces up, the antenna 114 can generate the electromagnetic field having the complete field pattern (exemplarily shown by dotted lines in FIG. 5). Namely, due to said configuration, the wireless communication device 100 can perform the function of wireless communication favorably.

To sum up, in the wireless communication device described in the embodiments of the invention, the host is covered by the protective jacket. Therefore, when the wireless communication device is not in use, the connector can be directly covered by the cap of the protective jacket, so as to achieve waterproof and dustproof protection. By contrast, once the wireless communication device is to be used, the host can be turned upside down, such that the connector of the wireless communication device can pass through the opening of the protective jacket and protrude from the protective jacket. As a result, the connector of the wireless communication device can be electrically connected to the peripheral device, and the protective jacket can still serve to protect the host.

Although the invention has been described with reference to the above embodiments, it will be apparent to one of the ordinary skill in the art that modifications to the described embodiments may be made without departing from the spirit of the invention. Accordingly, the scope of the invention will be defined by the attached claims rather than by the above detailed descriptions.

What is claimed is:

1. A protective jacket for covering an electronic device, the electronic device having a connector, the protective jacket comprising:
a jacket having a receiving space and an opening, the opening communicating with the receiving space and the outside of the jacket;
a fixing member configured on the jacket and outside the receiving space; and
a cap configured in the receiving space, the cap being opposite to the opening, wherein the electronic device is suitable for being placed in the receiving space and is in a first state or a second state relative to the jacket, the cap covers the connector when the electronic device is in the first state, and the connector passes through the opening and protrudes from the jacket when the electronic device is in the second state.

2. The protective jacket as recited in claim 1, wherein the cap and the opening are substantially located on the same axis.

3. The protective jacket as recited in claim 1, wherein the jacket is fixed to a peripheral device by the fixing member when the electronic device is in the second state.

4. The protective jacket as recited in claim 3, wherein when the electronic device is fixed to the peripheral device by the protective jacket, the connector of the electronic device is electrically connected to the peripheral device.

5. The protective jacket as recited in claim 3, the electronic device further having an antenna opposite to the connector, the antenna being located above the connector when the electronic device is fixed to the peripheral device by the protective jacket.

6. The protective jacket as recited in claim 1, wherein the cap, the fixing member, and the jacket are integrally formed.

7. The protective jacket as recited in claim 1, wherein a material of the cap and the jacket is a thermoplastic elastomer.

8. The protective jacket as recited in claim 1, wherein the fixing member is a back clipping mechanism, a sucker, a Velcro tape, or a magnetic/magnetizing device.

9. A wireless communication device comprising:
a host having a connector;
a protective jacket comprising:
a jacket having a receiving space and an opening, the opening communicating with the receiving space and the outside of the jacket; and
a cap configured in the receiving space, the cap being opposite to the opening, wherein the host is suitable for being placed in the receiving space and is in a first state or a second state relative to the jacket, the cap covers the connector when the host is in the first state, and the connector passes through the opening and protrudes from the jacket when the host is in the second state.

10. The wireless communication device as recited in claim 9, wherein the cap and the opening are substantially located on the same axis.

11. The wireless communication device as recited in claim 9, the protective jacket further comprising:
a fixing member configured on the jacket and outside the receiving space.

12. The wireless communication device as recited in claim 11, wherein the jacket is fixed to a peripheral device by the fixing member when the host is in the second state.

13. The wireless communication device as recited in claim 12, wherein when the wireless communication device is fixed to the peripheral device by the protective jacket, the connector of the wireless communication device is electrically connected to the peripheral device.

14. The wireless communication device as recited in claim 12, further having an antenna opposite to the connector, the antenna being located above the connector when the wireless communication device is fixed to the peripheral device by the protective jacket.

15. The wireless communication device as recited in claim 9, wherein the cap, the fixing member, and the jacket are integrally formed.

16. The wireless communication device as recited in claim 9, wherein a material of the cap and the jacket is a thermoplastic elastomer.

17. The wireless communication device as recited in claim 9, wherein the fixing member is a back clipping mechanism, a sucker, a Velcro tape, or a magnetic/magnetizing device.

18. The wireless communication device as recited in claim 9, wherein the connector is a universal serial bus connector or a high definition multimedia interface connector.
